(19) United States
(12) Patent Application Publication
(10) Pub. No.: US 2024/0362296 A1
(43) Pub. Date: Oct. 31, 2024

(54) REDUCED LATENCY TENSOR TRANSPOSITION WITHOUT REDUNDANT BUFFER

(71) Applicant: Microsoft Technology Licensing, LLC, Redmond, WA (US)

(72) Inventors: Yaron Baruch SHAPIRO, Petach Tikva (IL); Evgeny ROYZEN, Qiryat Ono (IL); Roi ELAD, Bnei Zion (IL)

(21) Appl. No.: 18/308,175

(22) Filed: Apr. 27, 2023

(51) Int. Cl. G06F 9/30; G06F 16/22; G11C 11/54

(52) U.S. Cl. CPC G06F 17/16; G06F 12/0207; G11C 11/54

(57) ABSTRACT

Techniques for reduced latency tensor transposition without using a redundant buffer are enabled. Reads from and writes to a buffer array may occur in different dimensions in a neural processing unit (NPU). For example, a set of tensor vectors may be written to a buffer in columnar format and read from the buffer in row format. As vectors of a first tensor are read from the buffer, incoming vectors from a second tensor may be transposed for storage in the dimension of already-read vectors without overwriting unread vectors. Write and read operations may alternately transpose vectors for continuous buffering in a single buffer with reduced latency.

### BACKGROUND

A neural processing unit (NPU) is a specialized processing unit (e.g., a microprocessor) configured to accelerate performance of machine learning (ML) tasks for applications including neural networks. An NPU may be implemented to free up a central processing unit (CPU) and/or graphical processing unit (GPU) to perform other (e.g., non-ML) computing tasks. For example, an NPU may improve the performance of a convolutional neural network (CNN) that processes images. In use, an NPU may receive input data in the form of tensors (multi-dimensional arrays of data), perform operations including convolutions on the input tensors, and generate a result.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Embodiments described herein enable reduced latency tensor transposition without using a redundant (extra) buffer. Reads from and writes to a buffer array are performed in a neural processing unit (NPU). According to tensor transposition, a set of tensor vectors may be written to the buffer in columnar format and read from the buffer in row format, and may be written to the buffer in row format and read from the buffer in columnar format. As vectors of a first tensor are read from the buffer, incoming vectors from a second tensor may be transposed for storage into the vacated dimension of already-read vectors without overwriting unread vectors. Write and read operations may alternately transpose vectors for continuous buffering in a single buffer with reduced latency. Technical advantages of reduced latency buffer transposition include reduced circuit/memory area usage (e.g., using 413023-US-NP a single buffer instead of two) and reduced power consumption (powering one buffer instead of two).

Further features and advantages of the embodiments, as well as the structure and operation of various embodiments, are described in detail below with reference to the accompanying drawings. It is noted that the claimed subject matter is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form a part of the specification, illustrate embodiments and, together with the description, further serve to explain the principles of the embodiments and to enable a person skilled in the pertinent art to make and use the embodiments.

FIG. 1 shows a block diagram of a compute cell with a zero delay transpose buffer in a neural processing unit, in accordance with an example embodiment.

FIG. 2 shows a block diagram of an output layer in a compute cell configured for reduced latency tensor transposition without using a redundant buffer, in accordance with an example embodiment.

FIG. 3 shows a block diagram of an example of a configurable reduced latency, tensor transpose buffer, in accordance with an example embodiment.

FIGS. 4A-4D show example views of operation of a reduced latency, tensor transpose buffer, in accordance with embodiments.

FIG. 5A shows a flowchart of a process for implementing reduced latency, tensor transpose buffering, in accordance with an embodiment.

FIG. 5B shows a flowchart of a process for implementing reduced latency, tensor transpose buffering, in accordance with an embodiment.

FIG. 6 shows a block diagram of an example computer system in which embodiments may be implemented.

The subject matter of the present application will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION

### I. Introduction

The following detailed description discloses numerous example embodiments. The scope of the present patent application is not limited to the disclosed embodiments, but also encompasses combinations of the disclosed embodiments, as well as modifications to the disclosed embodiments. It is noted that any section/subsection headings provided herein are not intended to be limiting. Embodiments are described throughout this document, and any type of embodiment may be included under any section/subsection. Furthermore, embodiments disclosed in any section/subsection may be combined with any other embodiments described in the same section/subsection and/or a different section/subsection in any manner.

### II. Example Embodiments

As set forth in the Background section, a neural processing unit (NPU) is a specialized processing unit (e.g., a microprocessor) configured to accelerate performance of machine learning (ML) tasks, e.g., for neural network applications. An NPU may be implemented to free up a central processing unit (CPU) and/or graphical processing unit (GPU) to perform other (e.g., non-ML) computing tasks. For example, an NPU may improve the performance of a convolutional neural network (CNN) that processes images. In use, an NPU may receive input data in the form of tensors, perform operations including convolutions on the input tensors, and generate a result. Data in a tensor may be organized in a multi-dimensional array of vectors.

An NPU may be limited in size (e.g., circuit area) and latency. NPU memory, such as a buffer in an NPU pipeline, may be implemented for continuous data flow (e.g., continuous writing and reading of tensor vectors to the buffer), to minimize latency (e.g., reduced latency due to avoiding wait time to empty the buffer). NPU memory may be implemented as a single buffer without additional buffers, for example, to minimize area. NPU memory may be variable (e.g., selectable sized array or matrix within memory), for example, to support scalability (e.g., handling a wider variety of ML tasks). NPU memory may be in the form of a matrix or array configured for reads and writes in different dimensions, for example, to implement reduced latency tensor transpose according to embodiments described herein.

A buffer may be written to and read from different dimensions. For example, tensor vectors may be written to a buffer in a column-by-column format and read from the buffer in a row-by-row format, or vice versa. Reading and writing in different dimensions may cause latency, for example, due to a delay in writing subsequent tensor vectors while buffered tensor vectors are being read to avoid overwriting unread vectors. Reading and writing in different dimensions may consume additional area, for example, by necessitating an additional buffer for continuous data flow.

For example, if input data is provided in “column format” (e.g., a tensor in column format loaded into memory column-by-column) column 0 of the input tensor may be written to memory on a first clock, column 1 of the input tensor may be written to the memory on the second clock, and so on. If output data is read in row format, the output may be row 0 of the output tensor (e.g., first byte of each input tensor) on a first clock after the first set of data (e.g., first tensor) is ready (e.g., stored in the memory), the output data may be row 1 of the output tensor on next clock, and so on.

The input data and output data may pause or may continue to flow depending on how the memory (e.g., or selectable/resizable matrix/array in the memory) is configured to operate. Input column data may pause to avoid overwriting while output row data is read from memory and output row data may pause while input column data is written to memory to be able to read full rows. Data may continue to flow with dual memories (e.g., buffers), alternating writes to the first buffer and second buffer and alternating reads from the first and second buffers. However, dual buffers use twice the memory and logic as a single buffer.

In embodiments, a memory configured for continuous read and write access supports continuous data flow, where “continuous data flow” refers to the filling of matrix rows/columns vacated by data of a first tensor with data of a second tensor, rather than waiting for the entire matrix to be emptied of data of the first tensor before beginning to read in data of the second tensor (such that the second tensor data is forced to “wait” or be buffered in an extra buffer). In this manner, the latency time in waiting to empty the matrix is avoided, as well as avoiding the need for an extra buffer to hold the second tensor data while the matrix is emptied of the first tensor data.

For instance, an N×N matrix may be configured (e.g., dynamically selected) for continuous, reduced latency access for multi-dimensional reads and writes (e.g., “column wise,” “row wise,” etc.). Input data may be continuously sampled (e.g., driven in or written) as a column and output data may be continuously sampled (e.g., driven out or read) as a row or vice versa. While a first tensor is read row by row from a matrix, a second tensor may be sampled in column format and driven (e.g., written) transposed into the matrix as rows (e.g., a column being written as a row into the just-vacated row) without overwriting unread data from the first tensor. The first tensor continues to be read while the second tensor continues to be written. The second tensor (buffered in transposed row format) may be read column by column and transposed to row format while a third tensor may be sampled and driven in as columns of the matrix. By writing incoming tensor data into dimensions of the matrix just vacated by read data, the matrix may be filled and vacated with no latency, and without the need for extra buffers, thereby increasing speed of NPU execution while reducing power consumption and circuit size. Table 1 shows an example of continuous read/write operations for a reduced latency tensor transposition without using a redundant buffer:

TABLE 1
Example of reduced latency tensor transposition without using a redundant
buffer for column format input data and row format output data

| Tensor # | Input data (column format) | Output data (row format) |
|---|---|---|
| Tensor 0 | Written to columns (no transpose) | read from rows (no transpose) |
| Tensor 1 | Written to rows (with transpose) | Read from columns (with transpose) |
| Tensor 2 | Written to columns (no transpose) | read from rows (no transpose) |
| Tensor 3 | Written to rows (with transpose) | Read from columns (with transpose) |
| . . . | . . . | . . . |

As shown in Table 1, writes and reads alternate performing transposition of sample input data and sampled stored data to provide continuous multi-dimensional reads and writes with reduced latency. As the stored tensor is read, the next tensor is sampled and driven to the matrix in the same dimension as the just read out tensor data without overwriting unread data. A single matrix memory (e.g., N×N matrix) may be formed with flip flops (FFs) to support transposition (e.g., of N×N pixels).

As set forth in the Summary section, methods, systems, and computer program products are disclosed herein for reduced latency tensor transposition without using a redundant buffer. Reads from and writes to a buffer array may occur in different dimensions, e.g., in a neural processing unit (NPU). For example, a set of tensor vectors may be written to a buffer in columnar format and read from the buffer in row format. As vectors of a first tensor are read from the buffer, incoming vectors from a second tensor may be transposed for storage in the dimension of already-read vectors without overwriting unread vectors. Write and read operations may alternately transpose vectors for continuous buffering in a single buffer with reduced latency. Technical advantages of reduced latency buffer transposition may include reduced area (e.g., one buffer instead of two) and/or reduced power consumption (powering one buffer instead of two). Furthermore, the latency time of waiting to empty the buffer array is avoided by writing in new tensor data into the buffer array as soon as row or column data is read out, rather than waiting for the entire array to be emptied before writing in new tensor data.

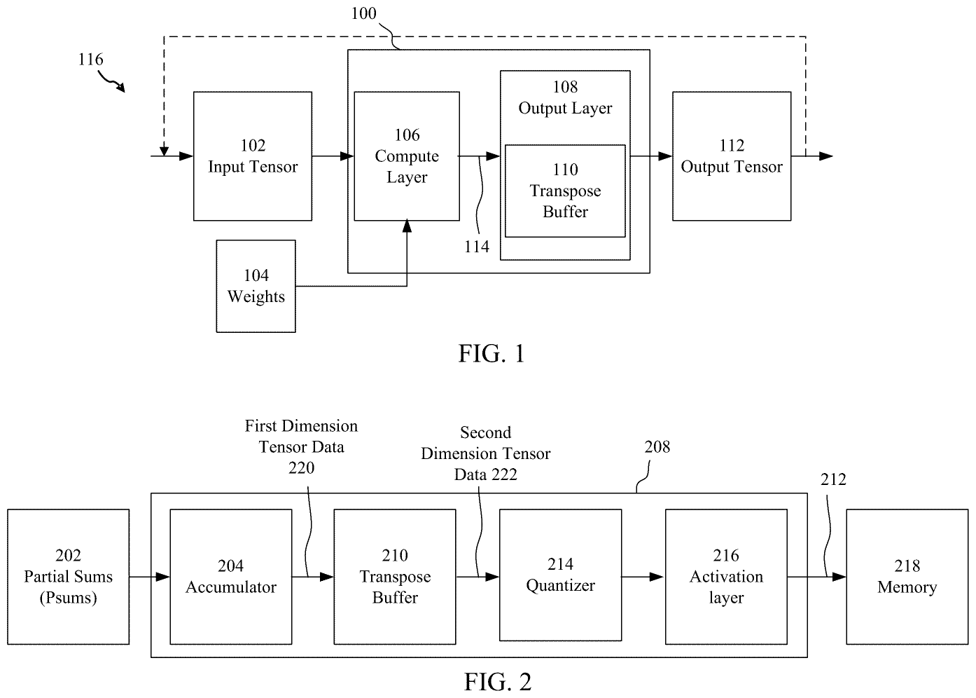

Embodiments may be configured in various ways in various embodiments. For instance, FIG. 1 shows a block diagram of an example of a NPU compute cell 100 (also referred to as a “compute cluster”) configured for reduced latency tensor transposition without using a redundant buffer in a NPU 116, in accordance with an example embodiment. NPU 116 may be, for example, a training and/or inference classification NPU. One or more NPUs 116 may be implemented, e.g., in a system on a chip (SoC). NPU(s) 116 may execute a deep neural network (DNN), such as a convolutional neural network (CNN)

As shown in FIG. 1, example NPU compute cell 100 may receive input tensor 102 and generate output tensor 112. Example NPU compute cell 100 may include compute layer 104, weights 106, and output layer 108 with reduced delay transpose buffer 110. These components of example NPU compute cell 100 (e.g., compute core) are described in further detail as follows.

Input tensor 102 includes an array of data corresponding to input information, such image pixel data (e.g., in bytes). For example, input tensor 102 may be three dimensional (3D) data (e.g., including red, blue, and green (RGB) pixel data of an input image). Input tensor 102 may be in NHWC format, indicating a batch size N, a height or number of columns H, a width or number of rows W, and a number of channels C. e.g., with bytes being ordered by HW coordinates (e.g., for pixels) channel by channel C (e.g., bytes 1, 2, 3, 4, etc. for HW coordinate 0,0 for channel 0 to x, then bytes 1, 2, 3, 4, etc. for HW coordinate 0,1 for channel 0 to x, etc.). Input tensor 102 may be in formats other than NHWC. Input tensor 102 may be, for example, 7×7, 14×14, 28×28, 56×56, 112×112, or other dimensioned array or matrix. Each column of data for a 7×7 input tensor in NCWH format may provide, for example, seven (7) bytes of data.

Weights 104 may be referred to as filters or kernel tensors. In some examples, weights may be four dimensional (4D), comprising three dimensional weights in multiple channels. For example, weights may include a dimension for each of RGB pixel data in multiple channels. Weights 104 may be part of a neural network model (e.g., ResNet-50, HourGlass-104). For example, weight 104 may be applied in multiple layers, e.g., 50, 100, 200 layers. Weights 104 may be used to extract or generate desired features from input tensor 102.

Compute layer 106 performs computations on input tensor 102 using weights 104. Compute layer 106 may include, for example, a systolic array (e.g., with H×W clusters) used to implement a CNN. Compute layer 106 may perform convolutions using input tensor 102 and weights 104. Compute layer 106 may perform, for example, iterative multiply-accumulate (MAC) operations on input tensor 102 using weights 104. Compute layer 106 may comprise multiple layers, e.g., 50, 100, 200 layers. Each layer in compute layer 106 may produce another tensor as input to another layer. In some examples, compute layer 106 may receive 3D input tensor 102 and 4D weights 104. Compute layer 106 may generate two-dimensional (2D) output, such as a set of vectors (e.g., vector sets). For example, an RGB input tensor may be processed by compute layer 106 into 64 channels of image data. In some examples, compute layer 106 may convert input tensors 102 in NHWC format to NCWH format (e.g., bytes ordered by CW (channel, row) coordinates in column by column/height by height format), providing output in column format (e.g., NCWH format) to output layer 108. Other examples may provide output to output layer 108 in other formats, e.g., row format.

Output layer 108 receives computed tensors 114 generated by compute layer 106. The computed tensors may be or may include partial sums (PSums). Output layer 108 may perform operations on the received computed tensors to generate output tensor 112. Output layer 108 may receive two dimensional (2D) input, e.g., tensor vectors. Output layer 108 may generate 2D output (e.g., tensor vectors), for example, as output tensor 112. In other implementations, the input received and output generated by output layer 108 may have the same or different data dimensions. Output layer 108 may include reduced delay transpose buffer 110.

Transpose buffer 110 may comprise any type of memory device. Transpose buffer 110 may be reconfigurable, e.g., by a controller in output layer 108. For example, transpose buffer 110 may comprise a selectable matrix or array, which may be selected based on output tensor size. Transpose buffer 110 may be selected as, for example, 7×7, 14×14, 28×28, 56×56, 112×112, or other dimensioned array or matrix.

Transpose buffer 110 may be configured for continuous read and write access in support of continuous data flow. In an example, an N×N matrix may be (re) configured (e.g., dynamically selected) for continuous, reduced latency access for multi-dimensional reads and writes (e.g., “column wise,” “row wise,” etc.). Transpose buffer 110 may be a single matrix memory (e.g., N×N matrix) formed with flip flops (FFs) to support transposition (e.g., of N×N tensors). Transpose buffer 110 may perform a hardware tensor transpose, e.g., without involvement of software. Input data may be continuously sampled (e.g., driven in or written) as a column and output data may be continuously sampled (e.g., driven out or read) as a row or vice versa. Other dimensional reads and writes may be supported. In an example, a computed tensor may be provided by compute layer 106 in column format. In some examples, output tensor 112 may be read row by row from transpose buffer 110. Computed tensors may be sampled/driven/written into transpose buffer 110 in alternating column-row format, with the columns for other tensor driven transposed from column to row format, matching the dimensional read format for output tensor 112 in alternating row-column format, with sampled columns (every other output tensor) driven transposed from column to row format.

Continuous reads and writes may occur without overwriting unread data. Stored tensors may continue to be read while a subsequent tensor continues to be written without overwriting unread data. Table 2 shows an example of continuous read/write operations for a reduced latency tensor transposition without using a redundant buffer in transpose buffer 110:

TABLE 2
Example of reduced latency tensor transposition without using
a redundant buffer for Reduced Delay Transpose Buffer

| Tensor # | Compute Layer 106 (column format) | Output Tensor 112 (row format) |
|---|---|---|
| Tensor 0 | Written to columns (no transpose) | Read from rows (no transpose) |
| Tensor 1 | Written to rows (with transpose) | Read from columns (with transpose) |
| Tensor 2 | Written to columns (no transpose) | Read from rows (no transpose) |
| Tensor 3 | Written to rows (with transpose) | Read from columns (with transpose) |
| . . . | . . . | . . . |

As shown in Table 2, writes and reads alternate performing transposition of transpose buffer input sampled from compute layer 106 and stored data sampled from transpose buffer 110 to provide continuous multi-dimensional reads and writes with reduced latency. As the stored tensor is read, the next tensor is sampled and driven to transpose buffer 110 in the same dimension as the read without overwriting unread data. For example, a first compute tensor in column format in compute layer 106 may be driven into transpose buffer 110 column by column until the complete tensor is stored in transpose buffer 110. While the first compute tensor in column format is read row by row from transpose buffer 110 as output tensor 112, a second tensor in column format may be sampled in column format from output layer 108 and driven (e.g., written) transposed into transpose buffer 110 as a row without overwriting unread data from the first tensor. The first tensor continues to be read as output tensor 112 while the second tensor continues to be written into transpose buffer 110. The second tensor (buffered in transposed row format in transpose buffer 110) may be read column by column and transposed to row by row format as output tensor 112 while a third tensor in column format may be sampled from compute layer 108 and driven/written as columns in transpose buffer 110.

Output tensor 112 may be, for example, a 2D tensor. As shown in FIG. 1 by the dashed line, output tensor 112 may be fed back as input tensor 102, for example, for one or more iterations.

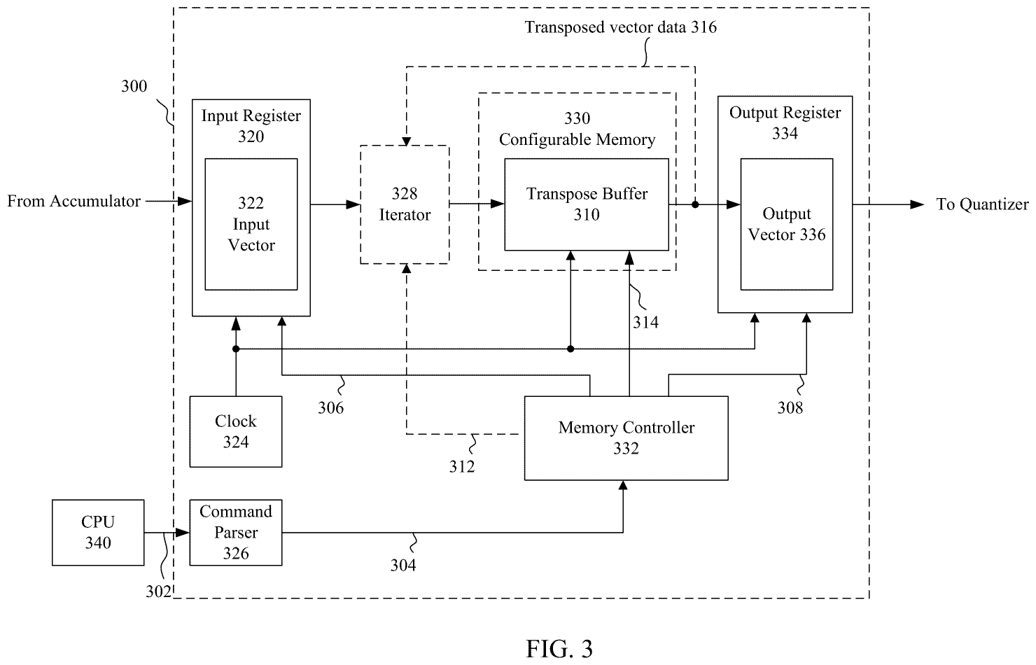

FIG. 2 shows a block diagram of an output layer 208 configured for reduced latency tensor transposition without using a redundant buffer, in accordance with an example embodiment. Example output layer 208 is an example of output layer 108 of FIG. 1. Example transpose buffer 210 is an example of transpose buffer 110. Example output layer 208 includes accumulator 204, transpose buffer 210, quantizer 214, activation layer 216 and memory 218. These components of output layer 208 are described in further detail as follows.

Accumulator 204 receives computed tensors from compute layer 106, e.g., after one or more convolutions of input tensors 102 and weights 104. The output generated by accumulator 204 may be stored in transpose buffer 210. Computed tensors may comprise or may include PSums 202. PSums 202 may be, for example, 24 bits. Accumulator 204 may add PSums to one or more computed tensors (e.g., columns in NCWH format). Data format may vary based on implementation. Accumulator 204 may be iterative. Accumulator 204 may use transpose buffer 210 to hold intermediate data for iterations. Transpose buffer 210 may, ultimately, hold fully accumulated data, e.g., upon completing convolutions and PSum accumulation on all channels.

Transpose buffer 210 may be similar to transpose buffer 110. First dimension tensor data 220 may be driven into transpose buffer 210 from accumulator 204 in a first dimension (e.g., column dimension) and driven out of (e.g., rotated) transpose buffer 210 to quantizer 214 in a second dimension (e.g., row dimension) as second dimension tensor data 222 to provide reduced latency tensor transposition. Read and write dimensions may alternate (e.g., with and without dimensional transpose as shown by example in Table 2) to provide continuous reading and writing of transpose buffer 210. Transposition may be performed by a hardware implementation. Transpose buffer 210 operations may be controlled, for example, by a state machine.

Quantizer 214 generates quantized tensor values. Quantizer 214 may be a set of quantizers, which may be (re) configured based on tensor size (e.g., 56×56, 112×112). Quantizer 214 may reduce a large set of received values to a smaller set of output values. Quantizer 214 may perform rounding and truncation operations on input data. Quantizer 214 may add bias (e.g., weights, not shown). Quantizer 214 may receive, for example, 24-bit PSums generated by accumulator 204. Quantizer 214 may reduce 24 bit input to 8-bit output while maintaining accuracy. Quantizer 214 generates quantized tensors.

Activation layer 216 receives quantized tensors with a reduced set of output values generated by quantizer 214. Activation layer 216 may generate output tensors 212 by applying an activation layer to quantized tensor values. Activation layer 216 may be configured to be any of a wide variety of activation functions, such as a rectified linear unit (ReLU), leaky ReLU, parametric ReLU (PRELU), exponential linear (ELU) function, Sigmoid, etc. The output of activation layer (e.g., output tensors 212) may indicate information learned or predicted based on information in input tensors (e.g., input tensor 102).

Memory 218 stores output tensors 212. Memory 218 may be any type of memory described elsewhere herein or otherwise known. Memory 218 may store output tensors 212 generated by a plurality of compute cells in an NPU.

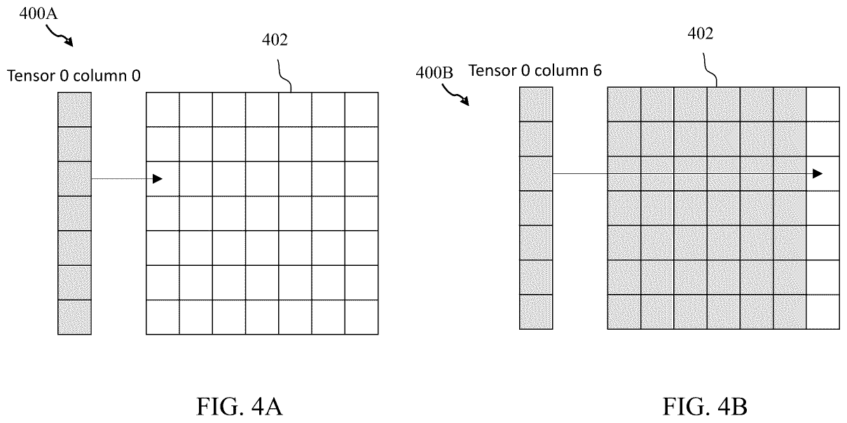

Zero delay transpose buffer 210 of FIG. 2 may be configured in various ways to perform its functions. For instance, FIG. 3 shows a block diagram of an example of a configurable reduced latency, tensor transpose buffer system 300 coupled to a CPU 340 of an NPU, in accordance with an example embodiment. System 300 includes an input register 320, a clock 324, a command parser 326, an iterator 328, a configurable memory 330, transpose buffer 310, a memory controller 332, and an output register 334. System 300 is described in further detail as follows.

Input register 320 receives input vectors 322 from accumulator. Input register 320 may store accumulated data (e.g., PSums) generated by accumulator 204 as input vectors 322. Input register 320 may store input tensor vectors in a dimension (e.g., as columns or rows). Input register 320 may store, for example, 1D (one dimensional) data. Input register 320 may be implemented, for example, as part of accumulator 204 or transpose buffer 310. Input register 320 may drive input vector data in from accumulator and stored input vector 322 out to iterator 328 based on clock 324 and/or based on one or more control signals 306 from memory controller 332 (e.g., data valid input).

Iterator 322 receives input vectors 322 from input register 320 based on clock 324. Iterator 328 may be implemented to iterate input vectors 322. For example, iterator 328 may comprise a vector adder configured to add input vector 322 to transposed vector output of transpose buffer 310. Iterated output may be provided to transpose buffer 310 in configurable memory 330. Iterator 328 may be controlled by memory controller 332 (e.g., if iterator 328 is implemented). For example, memory controller 332 may indicate the number of iterations and/or counter information to iterator 328 in a control signal 312.

Configurable memory 330 may comprise any type of memory, such as a register, latch, buffer, etc., created using any suitable technology, e.g., DRAM (dynamic random access memory, SRAM (static random access memory), and so on. Configurable memory 330 may be configurable into one or more zero delay transpose memories of various sizes, which enables tensors of various sizes to be handled in a same memory (rather than specific-sized memories). Configurable memory 330 may be selected and controlled, for example, by memory controller 332. For example, memory controller 332 may configure configurable memory 330 with one or more signals indicating a number of memory matrices, a size of each memory matrix, etc. Configurable memory 330 may be formed in a pipeline between an accumulator and a quantizer, for example.

Transpose buffer 310 may be similar to transpose buffer 110 or transpose buffer 210. Tensor data (e.g., vectors) may be driven into transpose buffer 310 from input register 320 or iterator 328 (e.g., depending on implementation) in a first dimension (e.g., column dimension) and driven out of transpose buffer 310 to output register 334 as output vectors 336 in a second dimension (e.g., row dimension) to provide reduced latency tensor transposition. Transpose buffer 310 may store 2D data. Read and write dimensions may alternate (e.g., with and without dimensional transpose as shown by example in Table 2) to provide continuous reading and writing of transpose buffer 310. Transposition may be performed by a hardware implementation. Transpose buffer 310 operations may be controlled, for example, by memory controller 332.

Transpose buffer 310 performs read and write operations based on clock 324 and/or based on one or more signals from memory controller 332. For example, memory controller 332 may provide a control signal 314 indicating read/write addresses (e.g., rows, columns) in the N×N matrix, which dimension transpose buffer 310 should write, which dimension transpose buffer 310 should read, whether to perform read transpose based on the data dimension of output vector 336, whether to perform write transpose based on the data dimension of input vector 322 (and/or iterated vector output of iterator 328), etc.

Output register 334 may be implemented, for example, as part of transpose buffer 310 or quantizer. Output register 334 receives the output of transpose buffer 310. Output register 334 may store accumulated, iterated data as output vectors 336. Output register 334 may store, for example, 1D data. Output register 334 may store output tensor vectors 336 in a dimension (e.g., as rows or columns). Output register 334 may be implemented, for example, as part of a quantizer or transpose buffer 310. Output register 334 may drive transposed vector data 316 in from transpose buffer 310 and vectors stored in output vector 336 out to a quantizer based on clock 324 and/or based on one or more control signals 308 from memory controller 332 (e.g., data valid input).

Central processing unit (CPU) 340 may comprise any type of processor, microcontroller, a microprocessor, signal processor, application specific integrated circuit (ASIC), and/or other physical hardware processor circuit) for performing computing tasks, such as program execution, signal coding, data processing, input/output processing, power control, and/or other functions. CPU 340 is configured to execute program code, such as an operating system and/or application programs (e.g., machine learning (ML), artificial intelligence (AI)), which may invoke use of one or more NPUs (e.g., as described herein), for example, to process images. CPU 340 may perform operations, e.g., based on execution of executable code, which may include one or more steps in processes/methods disclosed herein. CPU 340 may issue one or more commands 302 directed to one or more components in an NPU, such as memory controller 332.

Command parser 326 parses commands generated by CPU 340 (e.g., executing program code). Command parser 326 may decode commands and distribute parsed commands 304 to one or more NPU components, such as memory controller 332. Parsed commands provided to memory controller 332 may include, for example, transpose buffer matrix size, data validity indicator, counter control, filter type, number of iterations, etc.

Memory controller 332 issues one or more signals to control configuration and/or operation of input register 320, iterator 328, configurable memory 330, transpose buffer 310, and output register 334. Memory controller 332 may comprise, for example, one or more state machines. Memory controller 332 may determine and indicate the number of N×N matrices in transpose buffer 310. Memory controller 332 may determine and indicate the size of the N×N matrix in transpose buffer 310. Memory controller 332 may control inputs and outputs, for example, by controlling data valid signals based on determinations when data (e.g., vectors) in the pipeline are ready to be read/written. Memory controller 332 may determine when to sample input vectors 322 and output vectors 336, generating corresponding control signals 306 and 308 to input register 320 and output register 334. Memory controller 332 may determine where to sample input vector 322 and an iterated vector output of iterator 328 (by generating control signal 312) into the N×N matrix formed by transpose buffer 310. Memory controller 332 may determine what form or dimension to sample vector (e.g., as row or column) into input vector 322 and the iterated vector output of iterator 328 into the N×N matrix formed by transpose buffer 310. Memory controller 332 may control output, for example, by determining and indicating which vector to read in the N×N matrix, which format to read the vector (e.g., row or column dimension), when to read the vector, etc. Memory controller 332 all may indicate the size and/or type of filter. Memory controller 332 may determine and indicate the number of iterations performed by iterator 328.

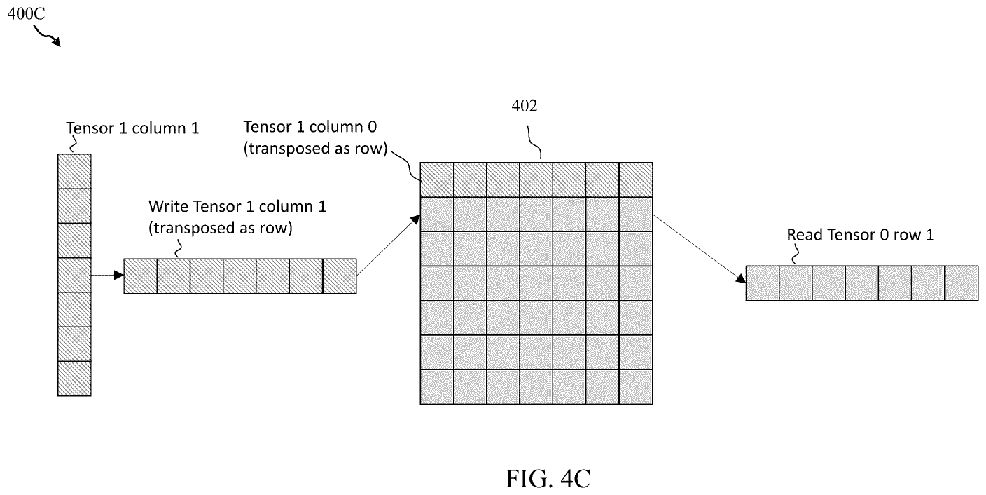

FIGS. 4A-4D show example views of operation of a zero delay transpose buffer 402, in accordance with embodiments. The examples shown in FIGS. 4A-4D are provided with respect to a 7×7 matrix. Other examples may implement different size matrices and memory to perform zero delay transposition. Examples 400A, 400B, 400C, and 400D show transpose buffer 402 in different states of operation as tensor vectors are driven in and out of ZTDB 402.

As shown in FIGS. 3 and 4A, memory controller 332 may configure configurable memory 330 for a 7×7 matrix as a zero delay transpose buffer 310. Input tensors (e.g., from accumulator) may be vectors in column form of seven (7) bytes. As shown in example transpose buffer 402, the first input vector (e.g., tensor 0 column 0) may be shifted/driven into the transpose buffer 402 in column form. As shown in example 400B of FIG. 4B, remaining vector columns of the first tensor (tensor 0) may be shifted/driven in to the transpose buffer 402, the last vector being tensor 0, column 6.

As shown in FIG. 4C, continuous read and write operations may begin after the first tensor is stored. As shown by the state of the transpose buffer 402 at example 400C, a first row vector of the first tensor (tensor 0, row 0) has already been read and the first vector of the second tensor (tensor 1, column 0) has already been transposed as a row in place of the first row of the first tensor (tensor 0, row 0). The second row vector of the first tensor (Tensor 0, row 1) is read. The second column vector of the second tensor (tensor 1, column 1) is transposed as a row in the matrix in place of the second row vector of the first tensor (Tensor 0, row 1). The continuous reading of the first tensor vectors as rows and the continuous writing of the second tensor vector columns transposed as rows continues until the 7×7 matrix is full of the second tensor vectors.

As shown in FIG. 4D, continuous read and continuous write operations continue for the second and third tensor vectors. As shown by the state of the transpose buffer 402 at example 400D, a first column vector of the second tensor (tensor 1, row 0) has already been read transposed as a row and the first vector of the third tensor (tensor 2, column 0) has already been written as a column (without transpose) in place of the first row of the second tensor (tensor 1, row 0). The second column vector of the second tensor (Tensor 1, row 1) is read as a column transposed to a row. The second column vector of the third tensor (tensor 2, column 1) is written as a column (without transpose) in the matrix in place of the second column vector of the second tensor (Tensor 1, column 1). The continuous reading of the second tensor vectors as columns with transpose to rows and the continuous writing of the third tensor vector columns as columns (without transpose) continues until the 7×7 matrix is full of the third tensor vectors. The process of continuous reading and writing of tensor vectors with zero delay transpose continues.

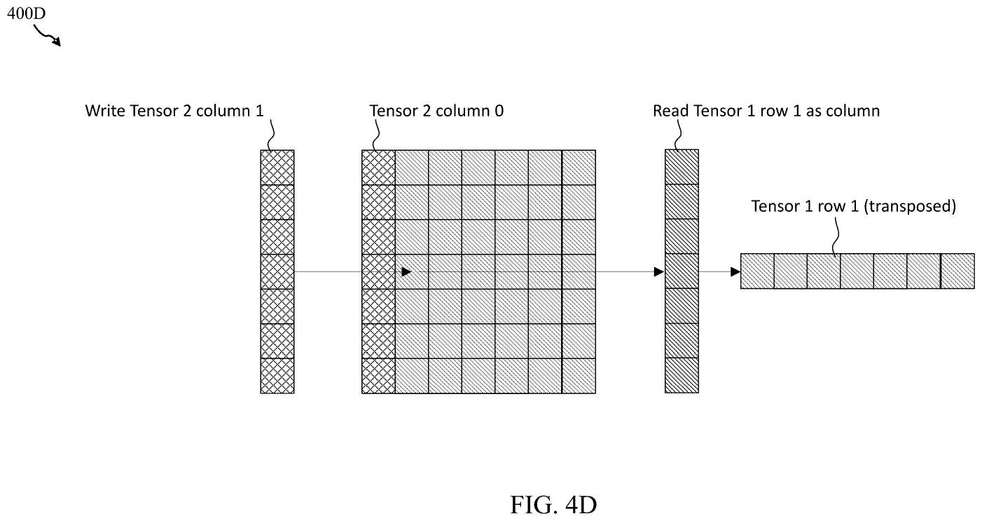

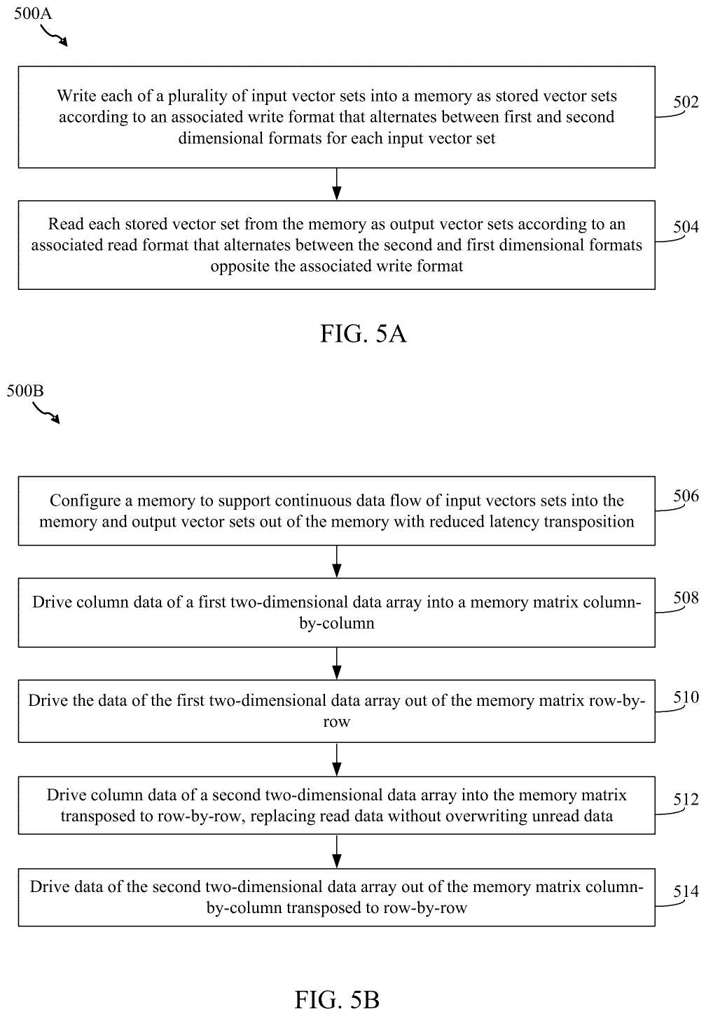

Note that the embodiments described herein may operate in a variety of ways. For instance, FIG. 5A shows a flowchart 500A of a process for implementing reduced latency, tensor transpose buffering, in accordance with an embodiment. The examples shown in FIGS. 1-4 may operate according to flowchart 500A at least in some embodiments. Example process 500A may be implemented, for example, by NPU 116, output layer 108, 208, memory controller 332, configurable memory 330, transpose buffer 110, 210, 310, etc. Various embodiments may implement one or more steps shown in FIG. 5A with additional and/or alternative steps. Further structural and operational embodiments will be apparent to persons skilled in the relevant art(s) based on the following description of FIG. 5A.

In step 502, each of a plurality of input vector sets may be written into a memory as stored vector sets according to an associated write format that alternates between first and second dimensional formats for each input vector set. For example, as shown in FIG. 3, memory controller 332 may control input register 320 and transpose buffer 310 to drive a set of vectors of a first tensor (e.g., input vector 322) into transpose buffer 310 in a first dimension, drive a set of vectors of a second tensor into transpose buffer 310 in a second dimension, drive a set of vectors of a third tensor into transpose buffer 310 in the first dimension, and so on.

In step 504, each stored vector set may be read from the memory as output vector sets according to an associated read format that alternates between the second and first dimensional formats opposite the associated write format. For example, as shown in FIG. 3, memory controller 332 may control transpose buffer 310 to drive the stored vector set of the first tensor out of transpose buffer 310 in the second dimension (e.g., opposite the first dimension in which vectors of the first tensor were stored), drive the stored vector set of the second tensor out of transpose buffer 310 in the first dimension (e.g., opposite the second dimension in which vectors of the second tensor were stored), drive the stored vector set of the third tensor out of transpose buffer 310 in the second dimension (e.g., opposite the first dimension in which vectors of the third tensor were stored), and so on.

FIG. 5B shows a flowchart 500B of another process for implementing reduced latency, tensor transpose buffering, in accordance with an embodiment. FIG. 5B shows an example of the procedure shown in FIG. 5A.

The examples shown in FIGS. 1-4 may operate according to flowchart 500B at least in some embodiments. Example process 500B may be implemented, for example, by NPU 116, output layer 108, 208, memory controller 332, configurable memory 330, transpose buffer 110, 210, 310, etc. Various embodiments may implement one or more steps shown in FIG. 5B with additional and/or alternative steps. Further structural and operational embodiments will be apparent to persons skilled in the relevant art(s) based on the following description of FIG. 5B.

In step 506, a memory may be configured to support continuous data flow of input vectors sets into the memory and output vector sets out of the memory with reduced latency transposition. For example, as shown in FIG. 3, memory controller 332 may configure reconfigurable memory 330 to form transpose buffer 310 as an N×N matrix in a pipeline between an accumulator and a quantizer.

In step 508, column data of a first two-dimensional data array may be driven (written) into a memory matrix column-by-column. For example, as shown in FIG. 3, memory controller 332 may control input register 320 and transpose buffer 310 to drive a set of vectors of a first tensor in a first dimension (column dimension) into transpose buffer 310 in the first dimension. FIGS. 4A and 4B show tensor 0, columns 0-6 being written as columns into a transpose buffer matrix.

In step 510, the first two-dimensional data array may be driven (read) out of the memory matrix row-by-row. For example, as shown in FIG. 3, memory controller 332 may control transpose buffer 310 to drive the stored set of vectors of the first tensor out of transpose buffer 310 in the second dimension (e.g., as rows without transpose). FIG. 4C shows tensor 0 being read out as rows (e.g., without transpose). Reading the stored tensor in row format may be referred to as reading the first byte stored in each column as the first row vector of the stored tensor, reading the second byte stored in each column as the second row vector of the stored tensor, and so on.

In step 512, column data of a second two-dimensional data array may be driven (written) into the memory matrix transposed to row-by-row, replacing read data without overwriting unread data. For example, as shown in FIG. 3, memory controller 332 may control input register 320 and transpose buffer 310 to drive a set of column vectors of a second tensor transposed in a second (row) dimension into transpose buffer 310. FIG. 4C shows tensor 1, columns 0-6 being written transposed as rows into a transpose buffer matrix.

In step 514, data of the second two-dimensional data array may be driven (read) out of the memory matrix column-by-column transposed to row-by-row. For example, as shown in FIG. 3, memory controller 332 may control transpose buffer 310 to drive the stored set of vectors of the second tensor out of transpose buffer 310 as columns transposed to rows. FIG. 4D shows tensor 1 being read out as columns transposed to rows.

### III. Example Computing Device Embodiments

As noted herein, the embodiments described, along with any circuits, components and/or subcomponents thereof, as well as the flowcharts/flow diagrams described herein, including portions thereof, and/or other embodiments, may be implemented in hardware, or hardware with any combination of software and/or firmware, including being implemented as computer program code (program instructions) configured to be executed in one or more processors and stored in a computer readable storage medium, or being implemented as hardware logic/electrical circuitry, such as being implemented together in a system-on-chip (SoC), a field programmable gate array (FPGA), and/or an application specific integrated circuit (ASIC). A SoC may include an integrated circuit chip that includes one or more of a processor (e.g., a microcontroller, microprocessor, digital signal processor (DSP), etc.), memory, one or more communication interfaces, and/or further circuits and/or embedded firmware to perform its functions.

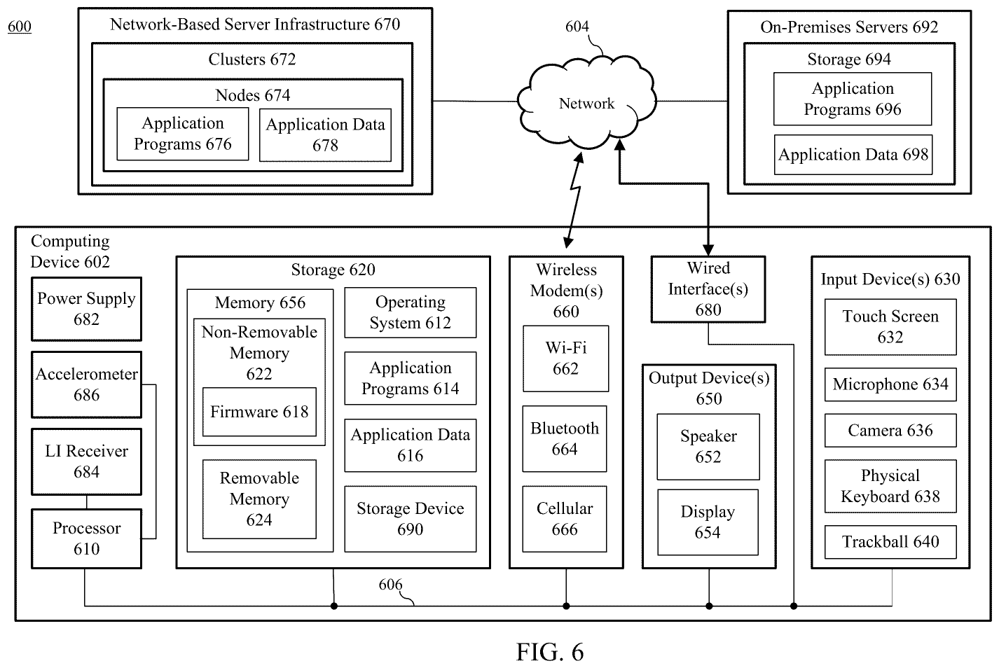

Embodiments disclosed herein may be implemented in one or more computing devices that may be mobile (a mobile device) and/or stationary (a stationary device) and may include any combination of the features of such mobile and stationary computing devices. Examples of computing devices in which embodiments may be implemented are described as follows with respect to FIG. 6. FIG. 6 shows a block diagram of an exemplary computing environment 600 that includes a computing device 602. Computing device 602 is an example of a computing device that may include NPU 116 shown FIG. 1, which may include one or more of the components of computing device 602. In some embodiments, computing device 602 is communicatively coupled with devices (not shown in FIG. 6) external to computing environment 600 via network 604. Network 604 comprises one or more networks such as local area networks (LANs), wide area networks (WANs), enterprise networks, the Internet, etc., and may include one or more wired and/or wireless portions. Network 604 may additionally or alternatively include a cellular network for cellular communications. Computing device 602 is described in detail as follows.

Computing device 602 can be any of a variety of types of computing devices. For example, computing device 602 may be a mobile computing device such as a handheld computer (e.g., a personal digital assistant (PDA)), a laptop computer, a tablet computer (such as an Apple iPad™), a hybrid device, a notebook computer (e.g., a Google Chromebook™ by Google LLC), a netbook, a mobile phone (e.g., a cell phone, a smart phone such as an Apple® iPhone® by Apple Inc., a phone implementing the Google® Android™ operating system, etc.), a wearable computing device (e.g., a head-mounted augmented reality and/or virtual reality device including smart glasses such as Google® Glass™, Oculus Quest 2® of Reality Labs, a division of Meta Platforms, Inc., etc.), or other type of mobile computing device. Computing device 602 may alternatively be a stationary computing device such as a desktop computer, a personal computer (PC), a stationary server device, a minicomputer, a mainframe, a supercomputer, etc.

As shown in FIG. 6, computing device 602 includes a variety of hardware and software components, including a processor 610, a storage 620, one or more input devices 630, one or more output devices 650, one or more wireless modems 660, one or more wired interfaces 680, a power supply 682, a location information (LI) receiver 684, and an accelerometer 686. Storage 620 includes memory 656, which includes non-removable memory 622 and removable memory 624, and a storage device 690. Storage 620 also stores an operating system 612, application programs 614, and application data 616. Wireless modem(s) 660 include a Wi-Fi modem 662, a Bluetooth modem 664, and a cellular modem 666. Output device(s) 650 includes a speaker 652 and a display 654. Input device(s) 630 includes a touch screen 632, a microphone 634, a camera 636, a physical keyboard 638, and a trackball 640. Not all components of computing device 602 shown in FIG. 6 are present in all embodiments, additional components not shown may be present, and any combination of the components may be present in a particular embodiment. These components of computing device 602 are described as follows.

A single processor 610 (e.g., central processing unit (CPU), microcontroller, a microprocessor, signal processor, ASIC (application specific integrated circuit), and/or other physical hardware processor circuit) or multiple processors 610 may be present in computing device 602 for performing such tasks as program execution, signal coding, data processing, input/output processing, power control, and/or other functions. Processor 610 may be a single-core or multi-core processor, and each processor core may be single-threaded or multithreaded (to provide multiple threads of execution concurrently). Processor 610 is configured to execute program code stored in a computer readable medium, such as program code of operating system 612 and application programs 614 stored in storage 620. The program code is structured to cause processor 610 to perform operations, including the processes/methods disclosed herein. Operating system 612 controls the allocation and usage of the components of computing device 602 and provides support for one or more application programs 614 (also referred to as “applications” or “apps”). Application programs 614 may include common computing applications (e.g., c-mail applications, calendars, contact managers, web browsers, messaging applications), further computing applications (e.g., word processing applications, mapping applications, media player applications, productivity suite applications), one or more machine learning (ML) models, as well as applications related to the embodiments disclosed elsewhere herein.

Any component in computing device 602 can communicate with any other component according to function, although not all connections are shown for ease of illustration. For instance, as shown in FIG. 6, bus 606 is a multiple signal line communication medium (e.g., conductive traces in silicon, metal traces along a motherboard, wires, etc.) that may be present to communicatively couple processor 610 to various other components of computing device 602, although in other embodiments, an alternative bus, further buses, and/or one or more individual signal lines may be present to communicatively couple components. Bus 606 represents one or more of any of several types of bus structures, including a memory bus or memory controller, a peripheral bus, an accelerated graphics port, and a processor or local bus using any of a variety of bus architectures.

Storage 620 is physical storage that includes one or both of memory 656 and storage device 690, which store operating system 612, application programs 614, and application data 616 according to any distribution. Non-removable memory 622 includes one or more of RAM (random access memory), ROM (read only memory), flash memory, a solid-state drive (SSD), a hard disk drive (e.g., a disk drive for reading from and writing to a hard disk), and/or other physical memory device type. Non-removable memory 622 may include main memory and may be separate from or fabricated in a same integrated circuit as processor 610. As shown in FIG. 6, non-removable memory 622 stores firmware 618, which may be present to provide low-level control of hardware. Examples of firmware 618 include BIOS (Basic Input/Output System, such as on personal computers) and boot firmware (e.g., on smart phones). Removable memory 624 may be inserted into a receptacle of or otherwise coupled to computing device 602 and can be removed by a user from computing device 602. Removable memory 624 can include any suitable removable memory device type, including an SD (Secure Digital) card, a Subscriber Identity Module (SIM) card, which is well known in GSM (Global System for Mobile Communications) communication systems, and/or other removable physical memory device type. One or more of storage device 690 may be present that are internal and/or external to a housing of computing device 602 and may or may not be removable. Examples of storage device 690 include a hard disk drive, a SSD, a thumb drive (e.g., a USB (Universal Serial Bus) flash drive), or other physical storage device.

One or more programs may be stored in storage 620. Such programs include operating system 612, one or more application programs 614, and other program modules and program data. Examples of such application programs may include, for example, computer program logic (e.g., computer program code/instructions) for implementing, utilizing, or supporting operation of one or more of NPU 116, along with any components and/or subcomponents thereof (e.g., command parser 326, memory controller 332), as well as the flowcharts/flow diagrams (e.g., flowcharts 500A and/or 500B) described herein, including portions thereof, and/or further examples described herein.

Storage 620 also stores data used and/or generated by operating system 612 and application programs 614 as application data 616. Examples of application data 616 include web pages, text, images, tables, sound files, video data, and other data, which may also be sent to and/or received from one or more network servers or other devices via one or more wired or wireless networks. Storage 620 can be used to store further data including a subscriber identifier, such as an International Mobile Subscriber Identity (IMSI), and an equipment identifier, such as an International Mobile Equipment Identifier (IMEI). Such identifiers can be transmitted to a network server to identify users and equipment.

A user may enter commands and information into computing device 602 through one or more input devices 630 and may receive information from computing device 602 through one or more output devices 650. Input device(s) 630 may include one or more of touch screen 632, microphone 634, camera 636, physical keyboard 638 and/or trackball 640 and output device(s) 650 may include one or more of speaker 652 and display 654. Each of input device(s) 630 and output device(s) 650 may be integral to computing device 602 (e.g., built into a housing of computing device 602) or external to computing device 602 (e.g., communicatively coupled wired or wirelessly to computing device 602 via wired interface(s) 680 and/or wireless modem(s) 660). Further input devices 630 (not shown) can include a Natural User Interface (NUI), a pointing device (computer mouse), a joystick, a video game controller, a scanner, a touch pad, a stylus pen, a voice recognition system to receive voice input, a gesture recognition system to receive gesture input, or the like. Other possible output devices (not shown) can include piezoelectric or other haptic output devices. Some devices can serve more than one input/output function. For instance, display 654 may display information, as well as operating as touch screen 632 by receiving user commands and/or other information (e.g., by touch, finger gestures, virtual keyboard, etc.) as a user interface. Any number of each type of input device(s) 630 and output device(s) 650 may be present, including multiple microphones 634, multiple cameras 636, multiple speakers 652, and/or multiple displays 654.

One or more wireless modems 660 can be coupled to antenna(s) (not shown) of computing device 602 and can support two-way communications between processor 610 and devices external to computing device 602 through network 604, as would be understood to persons skilled in the relevant art(s). Wireless modem 660 is shown generically and can include a cellular modem 666 for communicating with one or more cellular networks, such as a GSM network for data and voice communications within a single cellular network, between cellular networks, or between the mobile device and a public switched telephone network (PSTN). Wireless modem 660 may also or alternatively include other radio-based modem types, such as a Bluetooth modem 664 (also referred to as a “Bluetooth device”) and/or Wi-Fi modem 662 (also referred to as an “wireless adaptor”). Wi-Fi modem 662 is configured to communicate with an access point or other remote Wi-Fi-capable device according to one or more of the wireless network protocols based on the IEEE (Institute of Electrical and Electronics Engineers) 802.11 family of standards, commonly used for local area networking of devices and Internet access. Bluetooth modem 664 is configured to communicate with another Bluetooth-capable device according to the Bluetooth short-range wireless technology standard(s) such as IEEE 802.15.1 and/or managed by the Bluetooth Special Interest Group (SIG).

Computing device 602 can further include power supply 682, LI receiver 684, accelerometer 686, and/or one or more wired interfaces 680. Example wired interfaces 680 include a USB port, IEEE 1394 (Fire Wire) port, a RS-232 port, an HDMI (High-Definition Multimedia Interface) port (e.g., for connection to an external display), a DisplayPort port (e.g., for connection to an external display), an audio port, an Ethernet port, and/or an Apple® Lightning® port, the purposes and functions of each of which are well known to persons skilled in the relevant art(s). Wired interface(s) 680 of computing device 602 provide for wired connections between computing device 602 and network 604, or between computing device 602 and one or more devices/peripherals when such devices/peripherals are external to computing device 602 (e.g., a pointing device, display 654, speaker 652, camera 636, physical keyboard 638, etc.). Power supply 682 is configured to supply power to each of the components of computing device 602 and may receive power from a battery internal to computing device 602, and/or from a power cord plugged into a power port of computing device 602 (e.g., a USB port, an A/C power port). LI receiver 684 may be used for location determination of computing device 602 and may include a satellite navigation receiver such as a Global Positioning System (GPS) receiver or may include other type of location determiner configured to determine location of computing device 602 based on received information (e.g., using cell tower triangulation, etc.). Accelerometer 686 may be present to determine an orientation of computing device 602.

Note that the illustrated components of computing device 602 are not required or all-inclusive, and fewer or greater numbers of components may be present as would be recognized by one skilled in the art. For example, computing device 602 may also include one or more of a gyroscope, barometer, proximity sensor, ambient light sensor, digital compass, etc. Processor 610 and memory 656 may be co-located in a same semiconductor device package, such as being included together in an integrated circuit chip, FPGA, or system-on-chip (SOC), optionally along with further components of computing device 602.

In embodiments, computing device 602 is configured to implement any of the above-described features of flowcharts herein. Computer program logic for performing any of the operations, steps, and/or functions described herein may be stored in storage 620 and executed by processor 610.

In some embodiments, server infrastructure 670 may be present in computing environment 600 and may be communicatively coupled with computing device 602 via network 604. Server infrastructure 670, when present, may be a network-accessible server set (e.g., a cloud-based environment or platform). As shown in FIG. 6, server infrastructure 670 includes clusters 672. Each of clusters 672 may comprise a group of one or more compute nodes and/or a group of one or more storage nodes. For example, as shown in FIG. 6, cluster 672 includes nodes 674. Each of nodes 674 are accessible via network 604 (e.g., in a “cloud-based” embodiment) to build, deploy, and manage applications and services. Any of nodes 674 may be a storage node that comprises a plurality of physical storage disks, SSDs, and/or other physical storage devices that are accessible via network 604 and are configured to store data associated with the applications and services managed by nodes 674. For example, as shown in FIG. 6, nodes 674 may store application data 678.

Each of nodes 674 may, as a compute node, comprise one or more server computers, server systems, and/or computing devices. For instance, a node 674 may include one or more of the components of computing device 602 disclosed herein. Each of nodes 674 may be configured to execute one or more software applications (or “applications”) and/or services and/or manage hardware resources (e.g., processors, memory, etc.), which may be utilized by users (e.g., customers) of the network-accessible server set. For example, as shown in FIG. 6, nodes 674 may operate application programs 676. In an implementation, a node of nodes 674 may operate or comprise one or more virtual machines, with each virtual machine emulating a system architecture (e.g., an operating system), in an isolated manner, upon which applications such as application programs 676 may be executed.

In an embodiment, one or more of clusters 672 may be co-located (e.g., housed in one or more nearby buildings with associated components such as backup power supplies, redundant data communications, environmental controls, etc.) to form a datacenter, or may be arranged in other manners. Accordingly, in an embodiment, one or more of clusters 672 may be a datacenter in a distributed collection of datacenters. In embodiments, exemplary computing environment 600 comprises part of a cloud-based platform such as Amazon Web Services® of Amazon Web Services, Inc., or Google Cloud Platform™ of Google LLC, although these are only examples and are not intended to be limiting.

In an embodiment, computing device 602 may access application programs 676 for execution in any manner, such as by a client application and/or a browser at computing device 602. Example browsers include Microsoft Edge® by Microsoft Corp. of Redmond, Washington, Mozilla Firefox®, by Mozilla Corp. of Mountain View, California, Safari®, by Apple Inc. of Cupertino, California, and Google® Chrome by Google LLC of Mountain View, California.

For purposes of network (e.g., cloud) backup and data security, computing device 602 may additionally and/or alternatively synchronize copies of application programs 614 and/or application data 616 to be stored at network-based server infrastructure 670 as application programs 676 and/or application data 678. For instance, operating system 612 and/or application programs 614 may include a file hosting service client, such as Microsoft® OneDrive® by Microsoft Corporation, Amazon Simple Storage Service (Amazon S3)® by Amazon Web Services, Inc., Dropbox® by Dropbox, Inc., Google Drive™ by Google LLC, etc., configured to synchronize applications and/or data stored in storage 620 at network-based server infrastructure 670.

In some embodiments, on-premises servers 692 may be present in computing environment 600 and may be communicatively coupled with computing device 602 via network 604. On-premises servers 692, when present, are hosted within an organization's infrastructure and, in many cases, physically onsite of a facility of that organization. On-premises servers 692 are controlled, administered, and maintained by IT (Information Technology) personnel of the organization or an IT partner to the organization. Application data 698 may be shared by on-premises servers 692 between computing devices of the organization, including computing device 602 (when part of an organization) through a local network of the organization, and/or through further networks accessible to the organization (including the Internet). Furthermore, on-premises servers 692 may serve applications such as application programs 696 to the computing devices of the organization, including computing device 602. Accordingly, on-premises servers 692 may include storage 694 (which includes one or more physical storage devices such as storage disks and/or SSDs) for storage of application programs 696 and application data 698 and may include one or more processors for execution of application programs 696. Still further, computing device 602 may be configured to synchronize copies of application programs 614 and/or application data 616 for backup storage at on-premises servers 692 as application programs 696 and/or application data 698.

Embodiments described herein may be implemented in one or more of computing device 602, network-based server infrastructure 670, and on-premises servers 692. For example, in some embodiments, computing device 602 may be used to implement systems, clients, or devices, or components/subcomponents thereof, disclosed elsewhere herein. In other embodiments, a combination of computing device 602, network-based server infrastructure 670, and/or on-premises servers 692 may be used to implement the systems, clients, or devices, or components/subcomponents thereof, disclosed elsewhere herein.

As used herein, the terms “computer program medium,” “computer-readable medium,” and “computer-readable storage medium,” etc., are used to refer to physical hardware media. Examples of such physical hardware media include any hard disk, optical disk, SSD, other physical hardware media such as RAMs, ROMs, flash memory, digital video disks, zip disks, MEMs (microelectronic machine) memory, nanotechnology-based storage devices, and further types of physical/tangible hardware storage media of storage 620. Such computer-readable media and/or storage media are distinguished from and non-overlapping with communication media and propagating signals (do not include communication media and propagating signals). Communication media embodies computer-readable instructions, data structures, program modules or other data in a modulated data signal such as a carrier wave. The term “modulated data signal” means a signal that has one or more of its characteristics set or changed in such a manner as to encode information in the signal. By way of example, and not limitation, communication media includes wireless media such as acoustic, RF, infrared, and other wireless media, as well as wired media. Embodiments are also directed to such communication media that are separate and non-overlapping with embodiments directed to computer-readable storage media.

As noted above, computer programs and modules (including application programs 614) may be stored in storage 620. Such computer programs may also be received via wired interface(s) 680 and/or wireless modem(s) 660 over network 604. Such computer programs, when executed or loaded by an application, enable computing device 602 to implement features of embodiments discussed herein. Accordingly, such computer programs represent controllers of the computing device 602.

Embodiments are also directed to computer program products comprising computer code or instructions stored on any computer-readable medium or computer-readable storage medium. Such computer program products include the physical storage of storage 620 as well as further physical storage types.

### V. Additional Example Embodiments

Systems, methods, and instrumentalities are described herein related to reduced latency tensor transposition without using a redundant buffer. Reads from and writes to a buffer array may occur in different dimensions, e.g., in a neural processing unit (NPU). For example, a set of tensor vectors may be written to a buffer in columnar format and read from the buffer in row format. As vectors of a first tensor are read from the buffer, incoming vectors from a second tensor may be transposed for storage in the dimension of already-read vectors without overwriting unread vectors. Write and read operations may alternately transpose vectors for continuous buffering in a single buffer with reduced latency. Technical advantages of reduced latency buffer transposition may include reduced area (e.g., one buffer instead of two) and/or reduced power consumption (powering one buffer instead of two).

In an example, a device (e.g., a computing device comprising a neural processing unit (NPU)) may include a memory subject to reads and writes in different dimensions and a memory controller. The memory controller may be configured to write each of a plurality of input vector sets into the memory (e.g., an array or matrix) as stored vector sets according to an associated write format (e.g., arrangement or pattern) that alternates between first and second dimensional formats for each vector set. The memory controller may be configured to read each stored vector set from the memory as output vector sets according to an associated read format that alternates between the second and first dimensional formats opposite the associated write format.

In examples, the first dimensional format may be column-by-column and the second dimensional format is row-by-row.

In examples, the first dimensional format may be row-by-row and the second dimensional format may be column-by-column.

In examples, the write of a vector set to the memory using the second dimensional format may transpose the input vector set, creating a transposed stored vector set, and the read of the transposed stored vector set using the first dimensional format may transpose the output vector set.

In examples, each input vector set may be a set of tensor columns or tensor rows.

In examples, the device may comprise a neural processing unit (NPU) compute cell.

In examples, the memory may comprise a (e.g., pipeline) buffer in the NPU (e.g., output layer of the NPU) compute cell.

In examples, the writes of the input vector sets to the memory may replace read vectors in the stored vector sets without overwriting unread vectors in the stored vector sets.

In examples, the memory controller may be (e.g., further) configured to reconfigure a size of the memory.

In another example, a method may comprise writing each of a plurality of input vector sets into a memory as stored vector sets according to an associated write format that alternates between first and second dimensional formats for each vector set; and reading each stored vector set from the memory as output vector sets according to an associated read format that alternates between the second and first dimensional formats opposite the associated write format.

In examples, the first dimensional format may be column-by-column and the second dimensional format may be row-by-row or the first dimensional format may be row-by-row and the second dimensional format may be column-by-column.

In examples, the write of a vector set to the memory using the second dimensional format may transpose the input vector set, creating a transposed stored vector set, and the read of the transposed stored vector set using the first dimensional format may transpose the output vector set.

In examples, each input vector set may be a set of tensor columns or tensor rows.

In examples, the writing and the reading occur in a neural processing unit (NPU) compute cell.

In examples, the memory may occur in a buffer in the NPU compute cell.

In examples, the writes of the input vector sets to the memory may replace read vectors in the stored vector sets without overwriting unread vectors in the stored vector sets.

In examples, the method may (e.g., further) comprise reconfiguring a size of the memory.

In another example, a computer-readable storage medium has program instructions recorded thereon that, when executed by a processor, implements a method comprising: writing each of a plurality of input vector sets into a memory as stored vector sets according to an associated write format that alternates between first and second dimensional formats for each vector set; and reading each stored vector set from the memory as output vector sets according to an associated read format that alternates between the second and first dimensional formats opposite the associated write format. The writes of the input vector sets to the memory may replace read vectors in the stored vector sets without overwriting unread vectors in the stored vector sets.

In examples, the wherein the write of a vector set to the memory using the second dimensional format may transpose the input vector set, creating a transposed stored vector set, and the read of the transposed stored vector set using the first dimensional format may transpose the output vector set.

In examples, the writing and the reading may occur in a buffer in a neural processing unit (NPU) compute cell.

### VI. Conclusion

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

In the discussion, unless otherwise stated, adjectives modifying a condition or relationship characteristic of a feature or features of an implementation of the disclosure, should be understood to mean that the condition or characteristic is defined to within tolerances that are acceptable for operation of the implementation for an application for which it is intended. Furthermore, if the performance of an operation is described herein as being “in response to” one or more factors, it is to be understood that the one or more factors may be regarded as a sole contributing factor for causing the operation to occur or a contributing factor along with one or more additional factors for causing the operation to occur, and that the operation may occur at any time upon or after establishment of the one or more factors. Still further, where “based on” is used to indicate an effect being a result of an indicated cause, it is to be understood that the effect is not required to only result from the indicated cause, but that any number of possible additional causes may also contribute to the effect. Thus, as used herein, the term “based on” should be understood to be equivalent to the term “based at least on.”

Numerous example embodiments have been described above. Any section/subsection headings provided herein are not intended to be limiting. Embodiments are described throughout this document, and any type of embodiment may be included under any section/subsection. Furthermore, embodiments disclosed in any section/subsection may be combined with any other embodiments described in the same section/subsection and/or a different section/subsection in any manner.

Furthermore, example embodiments have been described above with respect to one or more running examples. Such running examples describe one or more particular implementations of the example embodiments; however, embodiments described herein are not limited to these particular implementations.

Moreover, according to the described embodiments and techniques, any components of systems, computing devices, servers, device management services, virtual machine provisioners, applications, and/or data stores and their functions may be caused to be activated for operation/performance thereof based on other operations, functions, actions, and/or the like, including initialization, completion, and/or performance of the operations, functions, actions, and/or the like.

In some example embodiments, one or more of the operations of the flowcharts described herein may not be performed. Moreover, operations in addition to or in lieu of the operations of the flowcharts described herein may be performed. Further, in some example embodiments, one or more of the operations of the flowcharts described herein may be performed out of order, in an alternate sequence, or partially (e.g., or completely) concurrently with each other or with other operations.

The embodiments described herein and/or any further systems, sub-systems, devices and/or components disclosed herein may be implemented in hardware (e.g., hardware logic/electrical circuitry), or any combination of hardware with software (e.g., computer program code configured to be executed in one or more processors or processing devices) and/or firmware.

While various embodiments have been described above, it should be understood that they have been presented by way of example only, and not limitation. It will be apparent to persons skilled in the relevant art that various changes in form and detail can be made therein without departing from the spirit and scope of the embodiments. Thus, the breadth and scope of the embodiments should not be limited by any of the above-described example embodiments, but should be defined only in accordance with the following claims and their equivalents.

1. A device, comprising:
a memory; and
a memory controller configured to control continuous data flow of input vectors sets into the memory and output vector sets out of the memory with reduced latency transposition by:
writing each of a plurality of input vector sets into the memory as stored vector sets according to an associated write format that alternates between first and second dimensional formats for each vector set; and
reading each stored vector set from the memory as output vector sets according to an associated read format that alternates between the second and first dimensional formats opposite the associated write format.

2. The device of claim 1, wherein the first dimensional format is column-by-column and the second dimensional format is row-by-row.

3. The device of claim 1, wherein the first dimensional format is row-by-row and the second dimensional format is column-by-column.

4. The device of claim 1, wherein the write of a vector set to the memory using the second dimensional format transposes the input vector set, creating a transposed stored vector set, and the read of the transposed stored vector set using the first dimensional format transposes the output vector set.

5. The device of claim 1, wherein each input vector set is a set of tensor columns or tensor rows.

6. The device of claim 1, wherein the device comprises a neural processing unit (NPU) compute cell.

7. The device of claim 6, wherein the memory comprises a buffer in the NPU compute cell.

8. The device of claim 1, wherein the writes of the input vector sets to the memory replace read vectors in the stored vector sets without overwriting unread vectors in the stored vector sets.

9. The device of claim 1, wherein the memory controller is further configured to support continuous data flow of input vectors sets into the memory and output vector sets out of the memory with reduced latency transposition by:
reconfiguring a size of the memory.

10. A method in a computing device, comprising:
writing each of a plurality of input vector sets into a memory as stored vector sets according to an associated write format that alternates between first and second dimensional formats for each vector set; and
reading each stored vector set from the memory as output vector sets according to an associated read format that alternates between the second and first dimensional formats opposite the associated write format.

11. The method of claim 10, wherein the first dimensional format is column-by-column and the second dimensional format is row-by-row or the first dimensional format is row-by-row and the second dimensional format is column-by-column.

12. The method of claim 10, wherein the write of a vector set to the memory using the second dimensional format transposes the input vector set, creating a transposed stored vector set, and the read of the transposed stored vector set using the first dimensional format transposes the output vector set.

13. The method of claim 10, wherein each input vector set is a set of tensor columns or tensor rows.

14. The method of claim 10, wherein the writing and the reading occur in a neural processing unit (NPU) compute cell.

15. The method of claim 14, wherein the memory comprises a buffer in the NPU compute cell.

16. The method of claim 10, wherein the writes of the input vector sets to the memory replace read vectors in the stored vector sets without overwriting unread vectors in the stored vector sets.

17. The method of claim 10, further comprising:
reconfiguring a size of the memory.

18. A computer-readable storage medium having program instructions recorded thereon that, when executed by a processor, implements a method comprising:
writing each of a plurality of input vector sets into a memory as stored vector sets according to an associated write format that alternates between first and second dimensional formats for each vector set; and
reading each stored vector set from the memory as output vector sets according to an associated read format that alternates between the second and first dimensional formats opposite the associated write format,
wherein the writes of the input vector sets to the memory replace read vectors in the stored vector sets without overwriting unread vectors in the stored vector sets.

19. The computer-readable storage medium of claim 18, wherein the wherein the write of a vector set to the memory using the second dimensional format transposes the input vector set, creating a transposed stored vector set, and the read of the transposed stored vector set using the first dimensional format transposes the output vector set.

20. The computer-readable storage medium of claim 18, wherein the writing and the reading occur in a buffer in a neural processing unit (NPU) compute cell.
